(19) United States
(12) Patent Application Publication
(10) Pub. No.: US 2008/0266795 A1
(43) Pub. Date: Oct. 30, 2008

(54) HEAT DISSIPATING DEVICE

(75) Inventor: SZU-WEI KUO, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/840,223

(22) Filed: Aug. 17, 2007

(30) Foreign Application Priority Data
Apr. 25, 2007 (CN) 200710200509.0

(51) Int. Cl. H05K 7/20

(52) U.S. Cl. 361/697

(57) ABSTRACT

A heat dissipation device includes a heat sink and a fan. The heat sink includes two first fins, and a plurality of second fins between the first fins. A locking portion extends outward from each first fin. The locking portions are located higher than the second fins. A sliding guideway is defined in each locking portion. Two flanges extend from two opposite sides of the fan respectively. The flanges are capable of engaging in the guideways of the heat sink to mount the fan to the heat sink.

### BACKGROUND

1. Field of the Invention

The present invention relates to a heat dissipating device.

2. Description of Related Art

During operation of an electronic component of an electronic device such as a central processing unit (CPU) of a computer, a large amount of heat is often produced. The heat must be quickly removed from the CPU to prevent unstable operation of or damage to the CPU. A heat sink is typically attached to an outer surface of the CPU to absorb the heat from the CPU. The heat absorbed by the heat sink is then dissipated to the air via a fan mounted to the heat sink.

Typically, the fan is mounted to the heat sink via a plurality of screws extending through the fan and screwed into the heat sink. It is cumbersome and inefficient to manipulate the screws when attaching or detaching the fan to or from the heat sink.

Consequently, it is required to provide a heat dissipating device which facilitates mounting or removing the fan to or from the heat sink.

### SUMMARY

A heat dissipation device includes a heat sink and a fan. The heat sink includes two first fins, and a plurality of second fins between the first fins. A locking portion extends outward from each first fin. The locking portions are located higher than the second fins. A sliding guideway is defined in each locking portion. Two flanges extend from two opposite sides of the fan respectively. The flanges are capable of engaging in the guideways of the heat sink to mount the fan to the heat sink.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is an exploded, isometric view of a heat dissipating device according to an embodiment of the present invention, the heat dissipating device including a fan;

FIG. 2 is an inverted view of the fan of FIG. 1; and

FIG. 3 is an assembled view of FIG. 1.

### DETAILED DESCRIPTION

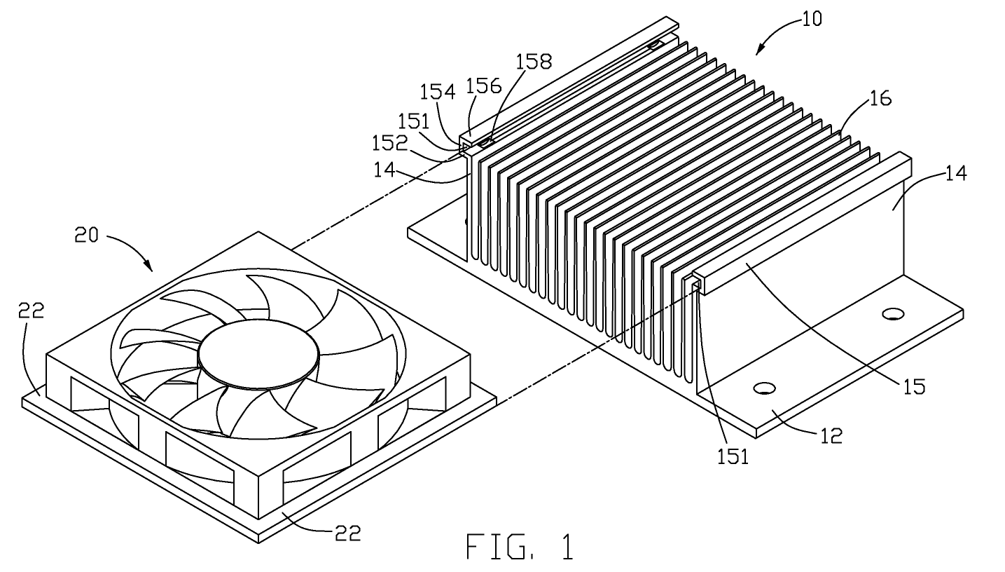

Referring to FIG. 1, in an exemplary embodiment of the invention, a heat dissipating device includes a heat sink 10, and a fan 20.

The heat sink 10 includes a base 12, two spaced first fins 14 extending from the base 12, and a plurality of second fins 16 extending in parallel from the base 12 between the first fins 14. Two generally U-shaped locking portions 15 are formed oppositely on top portions of the first fins 14 respectively. The locking portions 15 are higher than the second fins 16. Two opposite sliding guideways 151 are defined in the locking portions 15 respectively. Each locking portion 15 includes a bottom wall 152 extending outward from the top portion of the corresponding first fin 14, a sidewall 154 extending upward from a free side of the bottom wall 152, and a top wall 156 extending inward from a top edge of the sidewall 154. The bottom walls 152 are generally located in a same plane with the top portions of the second fins 16. Two recessed portions 158 are defined in each bottom wall 152. Each recessed portion 158 has an arc-shaped bottom wall.

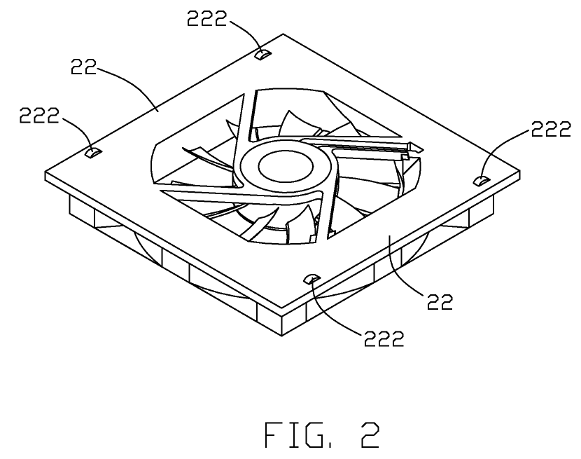

Referring also to FIG. 2, two parallel flanges 22 are arranged at opposite sides of the fan 20. Two blocks 222 protrude from a bottom surface of each flange 22. Each block 222 forms an arc-shaped top surface.

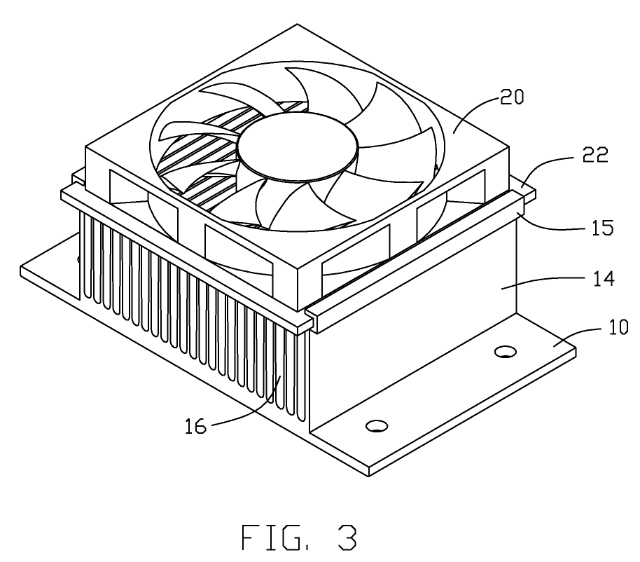

Referring also to FIG. 3, in assembly, the flanges 22 of the fan 20 are aligned with the guideways 151 of the heat sink 10, the fan 20 is pushed along top edges of the second fins 16 with the flanges 22 sliding in the guideways 151 of the heat sink 10. When the blocks 222 of the flanges 22 engage in the corresponding recessed portions 158 of the bottom wall 152 respectively, the fan 20 is securely fixed to the heat sink 10.

To detach the fan 20 from the heat sink 10, the fan 20 is pushed to disengage the blocks 222 of the flanges 22 from the recessed portions 158 of the bottom wall 152, the fan 20 is thus ready to be detached from the heat sink 10 along the guideways 151.

Alternatively, the blocks 222 can be formed on another surface of the flanges 22 respectively, for example, a lateral surface or top surface of the flange. Correspondingly, the recessed portions 158 are defined in an inner surface of the sidewall 154 or a bottom surface of the top wall 156.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipating device comprising:
a heat sink comprising two first fins, and a plurality of second fins between the first fins, two locking portions extending from the first fins respectively, the locking portions being located higher than the second fins, two guideways facing to each other being defined in the locking portions respectively; and
a fan comprising two flanges arranged at opposite sides thereof, the flanges capable of engaging in the guideways of the heat sink to mount the fan to the heat sink.

2. The heat dissipating device as described in claim 1, wherein a recessed portion is defined in a wall of each guideway, a block protrudes from the corresponding flange to engage in the corresponding recessed portion to fixedly attach the fan to the heat sink.

3. The heat dissipating device as described in claim 2, wherein each of the locking portions comprises a bottom wall extending outward from the top portion of the corresponding first fin, a sidewall extending upward from a free side of the bottom wall, and a top wall extending inward from a top portion of the sidewall, the walls cooperatively form the guideway.

4. The heat dissipating device as described in claim 3, wherein the recessed portion is defined in the bottom wall of the locking portion, the corresponding block protrudes from a bottom surface of the flange of the fan.

5. The heat dissipating device as described in claim 3, wherein the recessed portion is defined in the side wall of the locking portion, the corresponding block protrudes from a side surface of the flange of the fan.

6. The heat dissipating device as described in claim 3, wherein the recessed portion is defined in the top wall of the locking portion, the corresponding block protrudes from a top surface of the flange of the fan.

7. The heat dissipating device as described in claim 4, wherein the recessed portion comprises an arc-shaped bottom surface, the block comprises an arc-shaped top surface to suit the recessed portion.

8. The heat dissipating device as described in claim 3, wherein the bottom wall of the locking portion is generally located in a same plane with top edges of the second fins.

9. A heat dissipating device comprising:
a heat sink comprising a base, a pair of first fins extending from the base, and a plurality of second fins extending from the base between the first fins, a pair of locking portions extending from the first fins respectively, the locking portions defining a pair of guideways facing toward each other;
a fan with a pair of flanges formed at opposite sides thereof, the fan being slidably attached to the heat sink via the flanges sliding along the corresponding guideways; and
a pair of deformable locking structures respectively formed between the flanges and the corresponding locking portions to lock the fan with the heat sink, the fan being slidable away from the heat sink via the flanges sliding along the corresponding guideways when an external force is exerted thereon to overcome locking forces provided by the locking devices.

10. The heat dissipating device as described in claim 9, wherein each of the locking structures comprises a block with an arc-shaped convex surface formed at one of the flange and the corresponding locking portion, and a recess with an arc-shaped concave surface formed at the other one of the flange and the corresponding locking portion configured to fittingly receive the block to thereby lock the fan with the heat sink.

11. The heat dissipating device as described in claim 10, wherein each of the locking structures comprises a bottom wall extending perpendicularly from the corresponding first fin in a first direction, a sidewall extending perpendicularly from the bottom wall in a second direction perpendicular to the first direction, and a top wall extending perpendicularly from the sidewall in a third direction reverse to the first direction, the guideway of the locking portion being defined between the bottom wall, the sidewall, and the top wall.

12. The heat dissipating device as described in claim 11, wherein the second fins are parallel to each other with a plurality of channels formed therebetween, the channels extend from one side of the heat sink to an opposite side of the heat sink, and the guideways are parallel to the channels.

13. The heat dissipating device as described in claim 11, wherein the bottom walls of the structures are located in a same plane on which the fan is supported, and all of the second fins are not higher than the plane.
